(19) United States
(12) Patent Application Publication
(10) Pub. No.: US 2026/0186094 A1
(43) Pub. Date: Jul. 2, 2026

(54) SUBSPACE PROJECTION TO ESTIMATE SIGNAL INCONSISTENCIES

(71) Applicant: CANON MEDICAL SYSTEMS CORPORATION, Tochigi (JP)

(72) Inventors: Sebastian ROSENZWEIG, Zürich (CH); Bertram WILM, Stäfa (CH); Romain FROIDEVAUX, Gsteigwiler (CH)

(73) Assignee: CANON MEDICAL SYSTEMS CORPORATION, Tochigi (JP)

(21) Appl. No.: 19/417,527

(22) Filed: Dec. 12, 2025

Related U.S. Application Data
(60) Provisional application No. 63/739,382, filed on Dec. 27, 2024.

(51) Int. Cl. G01R 33/565; G01R 33/56; G01R 33/561; G01R 33/58; G06T 5/70; G06T 7/00; G06T 7/70

(52) U.S. Cl. CPC G01R 33/56509; G01R 33/5608; G01R 33/5611; G01R 33/583; G06T 5/70; G06T 7/0012; G06T 7/70; G06T 12/30; G06T 2207/10088; G06T 2207/30004; G06T 2207/30168; G06T 2210/41

(57) ABSTRACT

A method for detecting k-space signal inconsistency and suppressing related image artifacts in MRI data includes obtaining MRI data, the MRI data including MR signals as signal data over a period of time, the MRI data being represented as an acquired k-space; generating, based on the acquired k-space, a correlation matrix; determining a null space of the correlation matrix; determining a portion of the acquired k-space included in the null space of the correlation matrix to generate an error k-space; reconstructing an image based on a modified k-space generated using the error k-space, or by applying a penalty term that is a function of the error k-space.

### CROSS-REFERENCE TO RELATED APPLICATIONS

The present application claims the benefit of priority to provisional Application No. 63/739,382, filed on Dec. 27, 2024, the entire contents of which are incorporated herein by reference.

### FIELD

This disclosure relates to a method and apparatus for MRI imaging. In particular, a method for an error k-space determination and the generation of an artifact-reduced k-space are disclosed.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

MRI sequences can be prone to artifacts caused by inconsistent data acquisition arising from in-flow, patient motion, inaccurate or unexpected transmit RF (radio frequency) behavior, inaccurate or unexpected gradient fields, MR signal from volume with deficient gradient encoding (Annefact), and inaccurate or unexpected changes of RF receive coil sensitivities or the MR signal receive chain.

### SUMMARY

The disclosure additionally relates to a method for detecting k-space signal inconsistency and suppressing related image artifacts in magnetic resonance imaging (MRI) data includes obtaining magnetic resonance imaging (MRI) data, the MRI data including MR signals as signal data over a period of time, the MRI data being represented as an acquired k-space; generating, based on the acquired k-space, a correlation matrix; determining a null space of the correlation matrix; determining a portion of the acquired k-space included in the null space of the correlation matrix to generate an error k-space, the error k-space representing an artifact present in the MRI data; and reconstructing an image based on a modified k-space, or by applying a penalty term that is a function of the error k-space. The modified k-space is generated by performing one of: removing the generated error k-space from the acquired k-space to generate a clean k-space, as the modified k-space, or modifying the acquired k-space by calculating, based on the generated error k-space, weights for k-space samples used in image reconstruction, or omitting, based on the generated error k-space, k-space samples in image reconstruction.

Note that this summary section does not specify every embodiment and/or incrementally novel aspect of the present disclosure or claimed invention. Instead, this summary only provides a preliminary discussion of different embodiments. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows singular value decomposition of a calibration matrix.

FIG. 2 shows a flow artifact example and removal of the flow artifact, according to an embodiment of the present disclosure.

FIG. 3 shows a method for addressing undersampling for parallel imaging, according to an embodiment of the present disclosure.

FIGS. 4-8, 9A, and 9B show results of the disclosed method for artifact detection and suppression in various datasets, according to an embodiment of the present disclosure.

FIG. 10 is a schematic block diagram of a magnetic resonance imaging system, according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Motion from a patient/object during a magnetic resonance imaging (MRI) scan can introduce artifacts in reconstructed images (blurring, ghosting, signal loss, etc.), leading to misdiagnosis or requiring multiple scans to mitigate the motion errors. While some motion can be prevented, involuntary movements from the patient, such as swallowing, breathing, pulsatile flow, etc. can still occur and degrade the quality of the imaging results. This is especially common for pediatric and geriatric patients who dislike remaining in the MRI apparatus, cannot hold their breath for long periods of time, etc.

In MRI, the data acquisition does not occur directly in image space, but rather, in the frequency or Fourier space. Motion artifacts can materialize in a scan due to myriad factors, including the image structure, type of motion, MR pulse sequence settings, and k-space acquisition strategy. The center of k-space contains low spatial frequency information correlated to objects with large, low contrast features and smooth intensity variations, whereas the periphery of k-space contains high spatial frequency information correlated to edges, details, and sharp transitions. A majority of biological samples show very local spectral density in k-space centered around k=0. The kx and ky axes of k-space correspond to the horizontal (x-) and vertical (y-) axes of a two-dimensional (2D) image. The k-axes, however, represent spatial frequencies in the x- and y-directions, rather than positions.

For a three-dimensional (3D) image volume, the kz axis is also sampled, corresponding to a slice dimension of the image volume. Since the object in k-space is described by global planar waves, each point in k-space contains spatial frequency and phase information about every pixel in the final image. Conversely, each pixel in the image maps to every point in k-space. Simple reconstruction using an inverse FFT (iFFT) assumes the object has remained stationary during the time the k-space data were sampled. Therefore, errors from object motion have a pronounced effect on the final reconstructed image because a change in a single sample in k-space can affect the entire image. Since scan durations can take minutes in order to acquire the data necessary for image reconstruction, attempts have been made to accelerate the imaging speed as well as detect and correct for motion in images.

It should be noted that although the above description refers to the kx, ky, and kz axes as describing k-space acquired using Cartesian acquisition, the acquisition of the k-space data is not limited to Cartesian sampling. For example, non-Cartesian acquisition and image reconstruction can also be implemented. In such cases, the k-space is not acquired line by line, but using a spiral or radial trajectory, for instance. The acquired data can then be “gridded” to Cartesian k-space coordinates for image reconstruction. One skilled in the art will recognize that the methods described in this disclosure are applicable to both Cartesian and non-Cartesian k-space data.

Since the corrupted signal is contained in the acquired k-space data of all coils, it can be spread over the entire image. Further, it can be difficult to eliminate via data-consistency constraints using parallel imaging. Therefore, a method to eliminate the artifact, or to determine the location of artifact appearance (LAA) in the image is desired.

The GRAPPA kernel w_{xc} calibration can be formulated as described in the approach that applies GRAPPA and SENSE concept (see Uecker et al, “ESPIRIT—An Eigenvalue Approach to Autocalibrating Parallel MRI: Where SENSE meets GRAPPA,” Magn. Reson. Med., vol. 71, pp. 990-1001, 2014), yielding:

$${y}_{c}^{A C} = ℋ ( {k}^{A C} ) {P}_{x}^{T} {w}_{x c}$$

where w_{xc} is the GRAPPA weight for position x and coil c, Pₓ is the local sampling pattern at position x,

$${k}_{c}^{A C}$$

is the auto-calibration k-space of coil c, and [symbol] (k^{AC}) is the Hankel matrix of auto-calibration k-space. The Hankel matrix is constructed by sliding a patch through all auto-calibration regions and stacking the vectorized patches as columns into a matrix. In this equation, the GRAPPA weights w_{xc} are determined for the undersampling pattern specified by Pₓ and can be applied to all positions x that share that undersampling pattern. Since the auto-calibration region is the fully sampled, this equation allows determining weights for various kinds of undersampling patterns.

If e_{c} is a vector that is 1 at appropriate positions, by construction:

$$ℋ ( {k}^{A C} ) {e}_{c} = {k}_{c}^{A C} .$$

This then leads to:

$$0 = ℋ ( {k}_{c}^{A C} ) ( {P}_{x}^{T} {w}_{xC} - {e}_{c} )$$

Hence, a null-space of [symbol] (k^{AC}) exists, which hints at correlations between blocks of k-space. This null-space can be determined by analyzing the matrices of the SVD of [symbol] (k^{AC}):

$$ℋ ( {k}^{A C} ) = U S {V}^{H} .$$

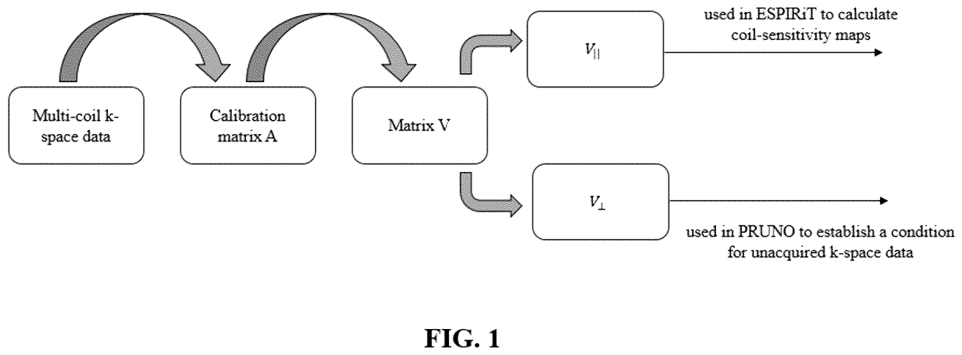

As FIG. 1 shows, a calibration matrix A, [symbol] (k^{AC}), can be constructed from the acquired multi-coil k-space data. The matrix A is of low-rank due to the non-empty null-space. By performing singular value decomposition (SVD), a matrix V can be obtained. In fact, the columns of V belonging to the non-zero singular values (V_{∥}) describe the correlations of k-space samples and can be seen as a generalization of the GRAPPA kernel. The information contained in V_{∥} is used in ESPIRIT to calculated coil-sensitivity maps, and the information contained in V_{⊥} is used in PRUNO to establish a condition for unacquired k-space data.

Described herein is a method for determining and removing an error k-space by exploiting the fact that un-corrupted k-space data patches should fully be in the space spanned by V_{∥} (and not in V_{⊥}). In contrast, signal-inconsistencies in the patches may not be readily describable by V_{∥} and therefore reside in V_{⊥}.

For example, an MRI image can include wave-like artifacts appearing in a spatial reconstruction of a brain. This can occur due to, for example, static blood flow that suddenly moves due to the heart pumping. This can lead to a signal inconsistency. A portion of the skull adjacent to the brain can be the origin of the wave-like artifacts. Notably, for such events like the blood inflow, some lines in k-space that are acquired can be inconsistent with neighboring lines. To assume that samples that are close in k-space, the samples fulfill a certain relationship. Thus, a sample can be interpolated from its neighbors. For the inflow problem, this condition, that one can estimate the value of a sample by its neighbors, is not a given anymore. This leads to the inconsistency and neighborhood relationships that can be exploited.

In one embodiment, the acquired multi-coil k-space kₐ can be modeled as the superposition of a clean k-space x and an artifact-comprising error k-space kₑ. The error k-space can represent unwanted features of the data and/or artifacts in the related image data. That is:

$${k}_{a} = κ + {k}_{e} ⇒ κ = {k}_{a} - {k}_{e} .$$

Thus, in order to determine and suppress the artifacts, the error k-space kₑ can be determined. This can be accomplished by using the Hankel operation (operator) H to extract the patches, which leads to:

$${ℋ}^{- 1} {V}_{⊥} {V}_{⊥}^{H} ℋ {k}_{a} = {ℋ}^{- 1} {V}_{⊥} {V}_{⊥}^{H} ℋ {k}_{e} ,$$

with the assumption that

$${ℋ}^{- 1} {V}_{⊥} {V}_{⊥}^{H} ℋκ = 0.$$

This an operation that essentially results in an output describing everything that is not consistent, with the assumption that neighboring samples should fulfill a certain relationship. This operation should highlight all the samples that are not consistent, and these inconsistent samples should represent the error k-space. At the same time, if this operation highlights inconsistent samples, it means that if the operation is applied to the clean k-space, the result should be zero because the clean k-space should not have any inconsistent samples.

The above equation is essentially a linear equation, or can be written as a linear minimization problem. This equation can be solved for kₑ using, for example, a conjugate gradient (CG) method (including a regularization) or via direct inversion. Alternatively, it can be assumed that patches of kₑ lie fully in the space spanned by V_{⊥}, yielding:

$${ℋ}^{- 1} {V}_{⊥} {V}_{⊥}^{H} ℋ {k}_{a} = {k}_{e} .$$

Based on the same theory, an alternative way to calculate kₑ using V_{∥} can be written as:

$${k}_{e} = {k}_{a} - {ℋ}^{- 1} {V}_{‖} {V}_{‖}^{H} ℋ {k}_{a} .$$

Therefore, as described below, the method of detecting k-space signal inconsistency and suppressing related image artifacts can include determining a null space or a row/column space of the correlation matrix, and determining a portion of the acquired k-space included in the null space or not included in the row/column space of the correlation matrix to generate a clean k-space.

The error k-space kₑ can be used to determine, for example, an Annefact-artifact or to reject non-consistent samples from the auto-calibration signal (ACS) region for calibration. Additionally, in some cases, e.g., for flow artifacts, the acquired k-space can iteratively be updated to obtain improved estimates of the error k-space:

$$κ \approx {k}_{a}^{( i + 1 )} = {k}_{a}^{( i )} - {k}_{e}^{( i )} .$$

Notably, the phase/magnitude-relationship between the channels in kₑ can be determined to efficiently remove the artifacts. Thus, prior knowledge of the source of the artifact can be included.

For flow artifacts, there can be knowledge of a location of artifact origin (LAO)-namely, a pulsating vessel. Here, several k-space locations can be corrupted when the acquisition of these locations happens during pulsation. The origin of the corruption is the spatial vessel location and can be determined using, for example, anatomic information, AI, etc.

In the image domain, this can be expressed by mₐ=S m_{ideal}+α mₑᵣᵣₒᵣ, which describes the acquired coil image as a superposition of the ideal image (weighted by coil sensitivities) and the error image (weighted by the coil-sensitivity at LAO, α=S (x_{LAO}, y_{LAO})).

The corresponding prior knowledge can be incorporated into the equation via kₑ: =αkₑ, where α is a [1, #coils] vector and kₑ is an [x, y] matrix (essentially, the Fourier Transform of mₑᵣᵣₒᵣ). This means, that the error k-space kₑ is spanned by α=S (x_{LAO}, y_{LAO}). Here, kₑ denotes a two-dimensional coefficient matrix, while kₑ is the corresponding k-space vector obtained by multiplying kₑ with the coil sensitivity vector α.

Thus, the previous equations can be represented as:

$${ℋ}^{- 1} {V}_{⊥} {V}_{⊥}^{H} ℋ {k}_{a} = {k}_{e} ,$$

$${\hat{k}}_{e} : = {αα}^{H} {k}_{e} , and$$

$$κ \approx {k}_{a}^{( i + 1 )} = {k}_{a}^{( i )} - {\hat{k}}_{e}^{( i )} .$$

Here, bold letters can be vectors.

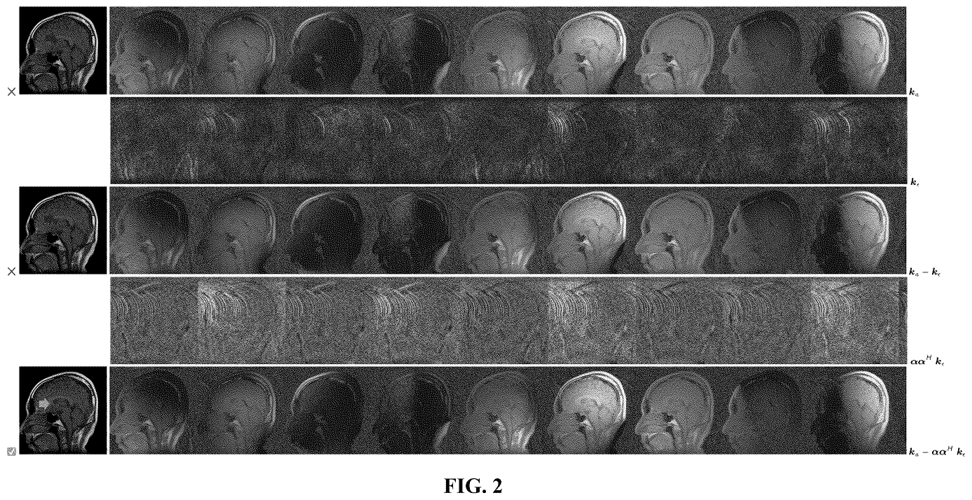

To this end, FIG. 2 shows a flow artifact example and the removal of the flow artifact, according to an embodiment of the present disclosure. In one embodiment, the effect of constraining the k-space error to the space spanned by a is shown. The first row of FIG. 2 shows the acquired k-space Fourier transform and the different coils. An image reconstruction from the acquired MRI data without any correction yields artifacts that can be targeted for removal. The second row of FIG. 2 shows the Fourier transform of the error k-space. In the third row of FIG. 2, simply subtracting the error k-space from the acquired k-space does not yield the desired results (the clean k-space) where the artifact is removed. Thus, in the fourth row of FIG. 2, the error k-space can be projected onto the vector α, which can then be subtracted from the acquired data (first row), followed by reconstruction to generate the fifth row. In the fifth row of FIG. 2, the artifact has been removed. Of course, the error k-space (with or without the projection onto the vector α) need not be removed from the acquired k-space, but can simply be omitted from subsequent processing steps.

In fully sampled regions (like the ACS), neighboring samples can be used to impose local consistency. Thus, the orthogonal space

$${V}_{⊥}^{A C S}$$

can be calculated directly from the ACS region. In undersampled regions, only acquired lines can contribute consistency information. Therefore, the calibration region can be adapted with the corresponding undersampling pattern to calculate the corresponding correlations. Thus, the orthogonal space

$${V}_{⊥}^{usamp}$$

can be calculated by undersampling of the ACS region. That is, to clean an undersampled region, the unacquired lines can be removed, which creates a k-space in which distant lines are now neighbors. Therefore, a space V_{⊥} can be calibrated in which these distant lines are neighbors as well. Therefore, the ACS region can be undersampled.

Described herein is an implementation of solving for the error k-space using the CG method. In one embodiment, the error k-space can be determined by solving the equation:

$${ℋ}^{- 1} {V}_{⊥} {V}_{⊥}^{H} ℋ {k}_{a} = {ℋ}^{- 1} {V}_{⊥} {V}_{⊥}^{H} ℋ {k}_{e}$$

In one embodiment, a least-squares method can be used to solve the above equation, based on the prior knowledge α, yielding:

$${argmin}_{{k}_{e}} {‖ {ℋ}^{- 1} {V}_{⊥} {V}_{⊥}^{H} ℋ {k}_{a} - {ℋ}^{- 1} {V}_{⊥} {V}_{⊥}^{H} ℋ {k}_{e} ‖}^{2} + λ {‖ {k}_{e} ‖}^{2} .$$

In one embodiment, other regularization terms can be included, such as constraining the error to certain regions in image space.

In one embodiment, the solution for the error k-space is then \hat{k}ₑ: =αkₑ, and the clean k-space is then given by κ≈kₐ−\hat{k}ₑ.

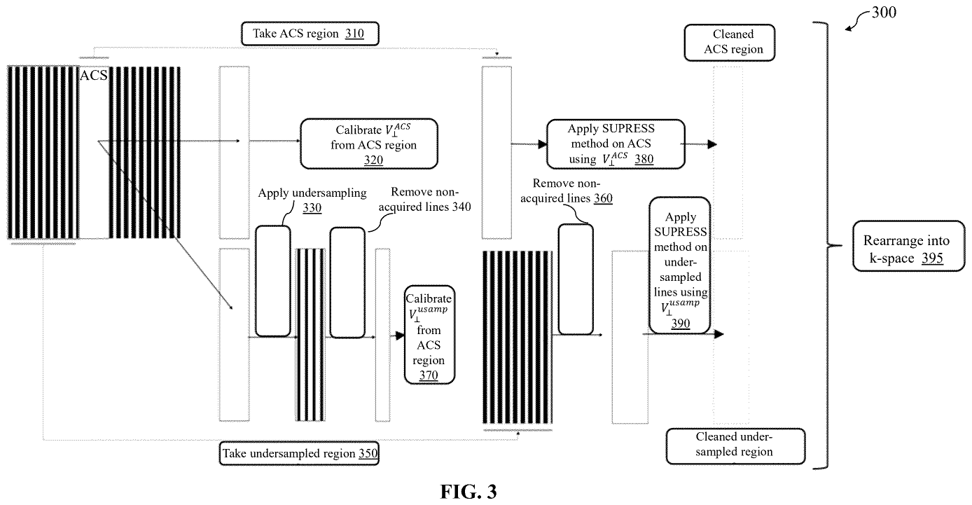

FIG. 3 shows a method 300 for addressing undersampling for parallel imaging, according to an embodiment of the present disclosure. In one embodiment, the acquired data can be undersampled, and the learned space V_{⊥} on which the k-space is projected can reflect the undersampling pattern.

Based on the approaches described above in paragraphs [0026]-[0031], a Subspace Projection to Estimate Signal Inconsistencies (SUPRESS) method can be applied, during which signal inconsistencies can be determined and accordingly suppressed by projecting k-space data to the orthogonal subspace V_{⊥}. In the SUPRESS method, the acquired k-space data is decomposed into a clean component in the signal subspace V_{∥} and an error component in the orthogonal subspace V_{⊥}. By identifying and removing the error component, the method can suppress k-space inconsistencies and reduce image artifacts. As FIG. 3 shows, the SUPRESS method can be applied to both the ACS region and the undersampled region to generate cleaned k-space data.

As illustrated in FIG. 3, in step 310, an ACS region is taken from the acquired data. In step 320, an orthogonal space

$${V}_{⊥}^{A C S}$$

is calibrated from the ACS region. In step 330, an undersampling operation is applied to the ACS region, and in step 340, corresponding non-acquired lines are removed. In step 350, an undersampled region of the acquired data is taken, and in step 360, the non-acquired lines of the region are removed. In step 370, an orthogonal space

$${V}_{⊥}^{usamp}$$

is calibrated from the ACS region. In step 380, the SUPRESS method is applied to the ACS region using the orthogonal space

$${V}_{⊥}^{A C S} ,$$

and in step 390, the SUPRESS method is applied to the undersampled lines using the orthogonal space

$${V}_{⊥}^{u s a m p} .$$

Accordingly, a cleaned AUS region and a cleaned undersampled region are generated, respectively. Finally, in step 395, the cleaned ACS region and the cleaned undersampled region are rearranged into a k-space for further image reconstruction.

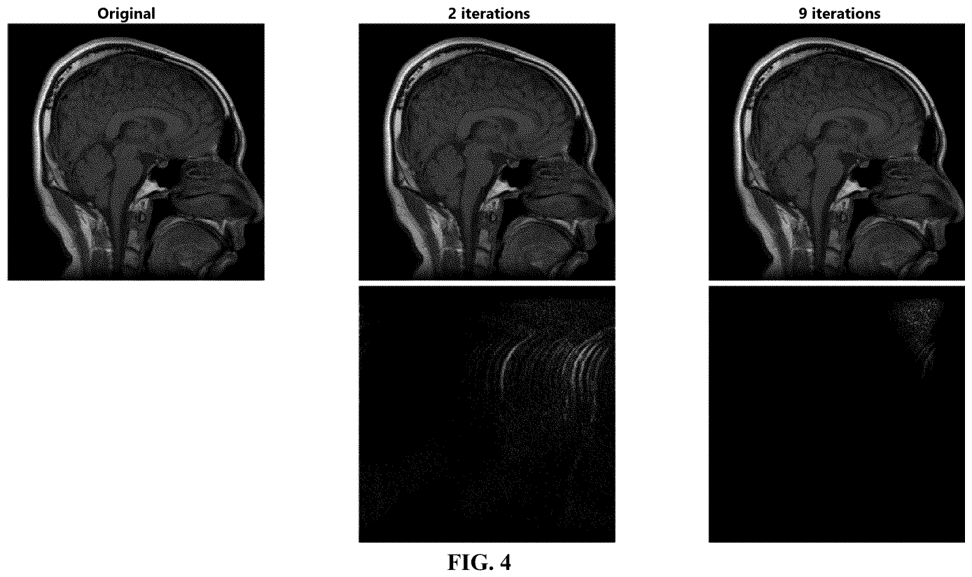

FIGS. 4-9 show results of the disclosed method for artifact detection and suppression in various datasets, according to an embodiment of the present disclosure.

As shown in FIG. 4, after two iterations (middle column), most of the artifacts are removed, as shown in the middle column of FIG. 4. The reconstructed image is shown on the top, and an error map is shown below. The error map mainly includes artifacts and noise, and no significant brain information. However, after additional iterations, such as nine iterations (right column of FIG. 4), noise amplification results. The error maps can show the error of one coil.

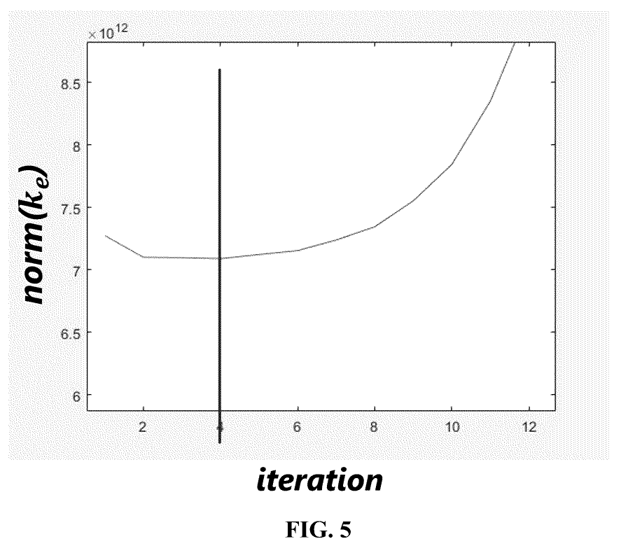

As shown in FIG. 5, the optimal number of iterations can be determined by considering the norm of the calculated kₑ in each iteration step. When the norm starts to become flat or rise, noise amplification is likely. One skilled in the art will recognize that this stopping criterion is merely an example and is not intended to be limiting or restrictive. Various other criteria can be used to determine when to terminate the iterations.

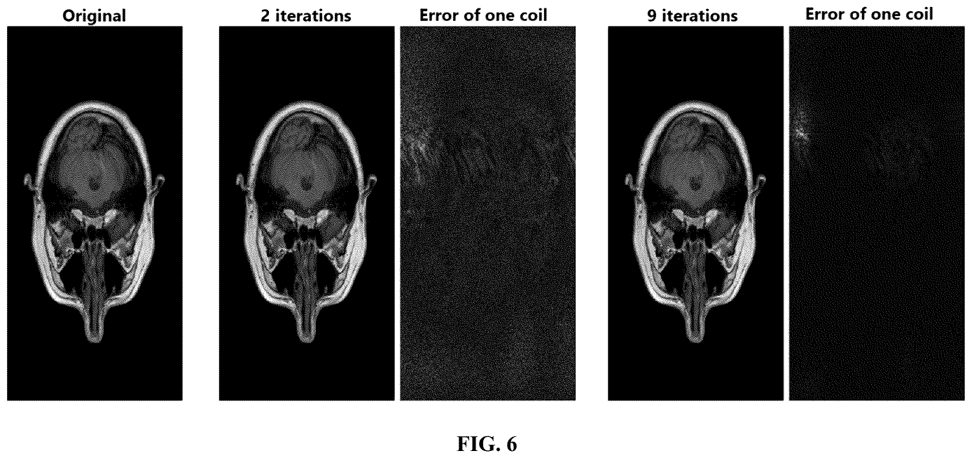

As shown in FIG. 6, after two iterations, artifacts are significantly reduced, but some still remain. After nine iterations, more artifacts are removed, but noise is amplified.

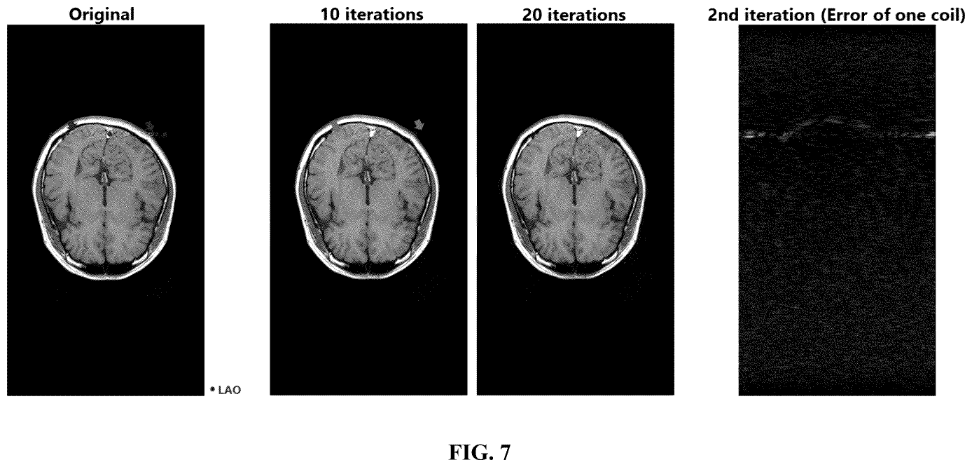

As shown in FIG. 7, the flow artifact is improved over 10 and 20 iterations, but as a trade-off, the signal-to-noise ratio (SNR) decreases. Since the flow artifact is in the vicinity of the LAO, the suppression effect is reduced. Notably, using the CG method with regularization could avoid excessive SNR amplification.

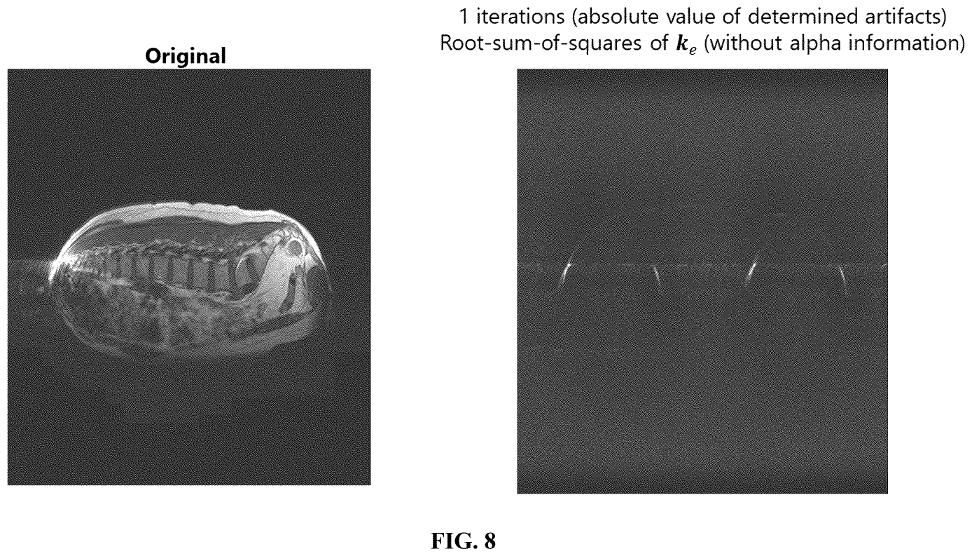

As shown in FIG. 8, an undersampled dataset was used to see the Annefact artifacts. Furthermore, the phase information was not used here. However, the Annefact artifacts can still be localized, as shown on the right side of FIG. 8.

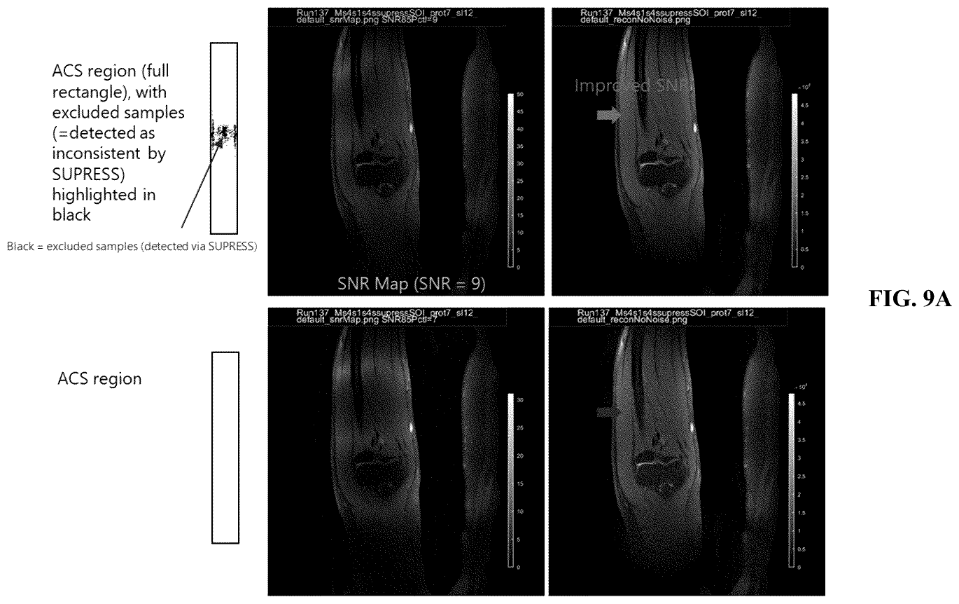

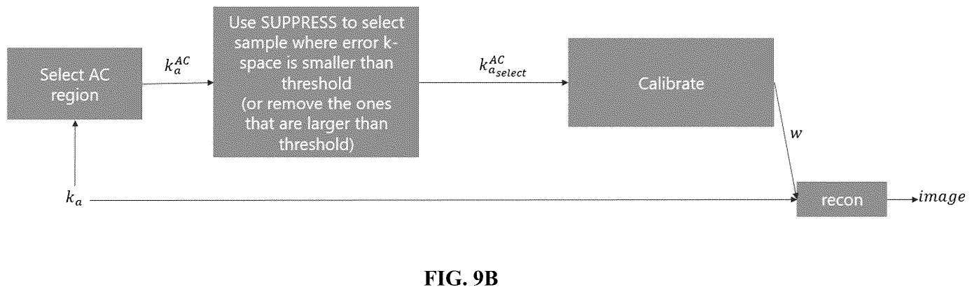

FIGS. 9A and 9B show ACS region selection for Exsper/GRAPPA kernel calibration, according to an embodiment of the present disclosure. Notably, FIGS. 9A and 9B show reconstructions using the ACS region where samples have been excluded using the described method's provided information (top), and without sample exclusion (bottom). To calibrate the Exsper kernel (GRAPPA kernel), it can be beneficial to exclude inconsistent parts from the ACS region from kernel calibration. The kₑ estimated with the method described herein can provide information on which samples to exclude from the kernel calibration (e.g., via thresholding the kₑ magnitude). It was shown that the corresponding calibrated kernel (with excluded “inconsistent” samples) provides better image SNR compared to the kernel calibrated without “inconsistent” sample exclusion. An alternative implementation of the described method is to calculate kₑ as being not part of v_{∥}, using:

$${k}_{e} = {k}_{a} - {ℋ}^{- 1} {V}_{‖} {V}_{‖}^{H} {ℋk}_{a} .$$

Note that the reconstruction of an image based on the generated k-space is not limited to any specific reconstruction domain. In various embodiments, the reconstruction can be performed in the k-space domain (e.g., GRAPPA-like reconstruction) or in the image domain (e.g., SENSE-like reconstruction), for instance.

In one embodiment, a method for determining k-space inconsistency (which leads to image space errors) and artifact removal are summarized herein.

In one embodiment, magnetic resonance imaging (MRI) data can be obtained, the MRI data including MR signals as signal data over a period of time, the MRI data being represented as an acquired k-space.

In one embodiment, a projection space can be determined. To achieve this, a suitable sample from the acquired k-space can be taken, which can be fully sampled or undersampled. A Hankel Matrix (or other correlation matrices, such as Toeplitz or similar) can be constructed. A null space of the matrix can be determined by performing singular value decomposition (SVD), determining a singular value threshold (e.g., Marchenku-Pastur) or threshold depending on a maximum singular value (e.g., 1% of max. singular value), and determining a singular value hard threshold (VH) from the SVD, and keeping only those eigenvectors that belong to eigenvalues smaller than the determined threshold.

In other embodiments, principal component analysis (PCA) or other signal decomposition methods can also be used to determine the null space.

In one embodiment, for image space, the projection operator

$${V}_{⊥} {V}_{⊥}^{H}$$

can be constructed or a spatial nulling map can be constructed, for example, as described in Hu et al., “Parallel Imaging Reconstruction Using Spatial Nulling Maps,” Magn. Reson. Med., vol. 90., pp. 502-519, 2023.

In one embodiment, an artifact or k-space inconsistency can be detected via

$${ℋ}^{- 1} {V}_{⊥} {V}_{⊥}^{H} {ℋk}_{a} = {k}_{e} .$$

Note that

$${V}_{⊥}^{H} ℋ$$

may also be replaced by a convolution operation with kernels specified by V_{⊥}. In one embodiment, the artifact image can be obtained via a root sum of squares, or imgₑᵣᵣ=RSS(FFT(kₑ)). In one embodiment, samples to be excluded can be determined, e.g., for GRAPPA kernel calibration. This can be given by: (thresh(abs(kₑ))>0. In the image space, the Fourier transform of kₐ spatial nulling maps can be projected.

In one embodiment, an artifact or k-space inconsistency can be detected and removed. To achieve this, the location of origin of an artifact (LAO) (e.g., a pulsating vessel) is determined using, for example, anatomical information, AI, etc., and the corresponding coil sensitivity at the location of origin of the artifact can be determined, which can be given by α=S (x_{LAO}, y_{LAO}).

In one embodiment, the artifact can be removed via a CG method or using an iterative process. The iteration can be given as:

$${ℋ}^{- 1} {V}_{⊥} {V}_{⊥}^{H} {ℋk}_{a} = {k}_{e} \to {\hat{k}}_{e} : = {αα}^{H} {k}_{e} ( project onto space spanned by α ) \to κ \approx {k}_{a}^{( i + 1 )} = {k}_{a}^{( i )} - {\hat{k}}_{e}^{( i )} .$$

As one advantage, the described method is more robust and faster than the ALOHA method.

As one advantage, the described method uses the entire space of correlations by exploiting the null-space idea, whereas the COCOA method uses only a single weighting kernel per coil for k-space correlation. Further, the COCOA method requires the tedious masking of corrupted k-space lines.

As another advantage, the described method does not tend to identify fat-tissue as artifact and remove it, like extended SENSE does. To remove e.g., a flow-artifact, extended SENSE needs to perform a CG-SENSE reconstruction, whereas the described method cleans the acquired k-space. The reconstruction method can then be freely chosen.

Further, ESPIRIT and PRUNO are image reconstruction techniques and not directly related to the goal of the described method, i.e., artifact detection and suppression.

In the embodiments described above, an image is reconstructed based on the modified k-space obtained using the error k-space. In other embodiments, the error k-space can be used in the image reconstruction through a penalty (or regularization) term that is a function of the error k-space, for example.

In one embodiment, an image x can be reconstructed by minimizing a cost function that includes a data-consistency term, |Ax−y|, and a penalty term, R(error_k_space), where x represents the image to be reconstructed, A represents the encoding, y represents the measured data, and R(error_k_space) is constructed as a function of the error k-space (and, optionally, of additional parameters). In this manner, the error k-space can influence the reconstructed image through the penalty term.

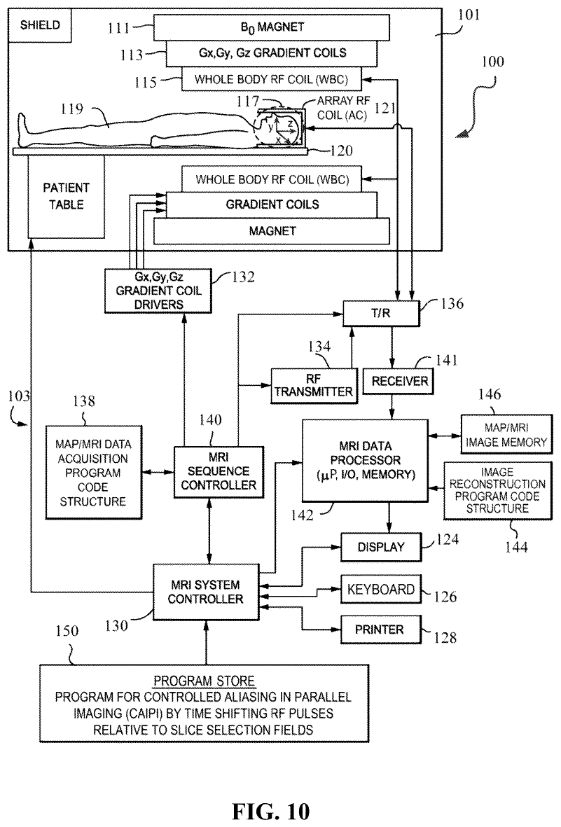

Referring now to FIG. 10, a non-limiting example of a magnetic resonance imaging (MRI) system 100 is shown. The MRI system 100 depicted in FIG. 10 includes a gantry 101 (shown in a schematic cross-section) and various related system components 103 interfaced therewith. At least the gantry 101 is typically located in a shielded room. The MRI system geometry depicted in FIG. 10 includes a substantially coaxial cylindrical arrangement of the static field B0 magnet 111, a Gx, Gy, and Gz gradient coil set 113, and a large whole-body RF coil (WBC) assembly 115. Along a horizontal axis of this cylindrical array of elements is an imaging volume 117 shown as substantially encompassing the head of a patient 119 supported by a patient table 120.

One or more smaller array RF coils 121 can be more closely coupled to the patient's head (referred to herein, for example, as “imaging object” or “object”) in imaging volume 117. As those in the art will appreciate, compared to the WBC (whole-body coil), relatively small coils and/or arrays, such as surface coils or the like, are often customized for particular body parts (e.g., arms, shoulders, elbows, wrists, knees, legs, chest, spine, etc.). Such smaller RF coils are referred to herein as array coils (AC) or phased-array coils (PAC). These can include at least one coil configured to transmit RF signals into the imaging volume, and a plurality of receiver coils configured to receive RF signals from an object, such as the patient's head, in the imaging volume.

The MRI system 100 includes an MRI system controller 130 that has input/output ports connected to a display 124, a keyboard 126, and a printer 128. As will be appreciated, the display 124 can be of the touch-screen variety so that it provides control inputs as well. A mouse or other I/O device(s) can also be provided.

The MRI system controller 130 interfaces with an MRI sequence controller 140, which, in turn, controls the Gx, Gy, and Gz gradient coil drivers 132, as well as the RF transmitter 134, and the transmit/receive switch 136 (if the same RF coil is used for both transmission and reception). The RF transmitter 134 may be composed of two or more transmitter channels for driving two or more RF transmit coils or ports on coils, as is used for RF shimming. The MRI sequence controller 140 includes suitable program code structure 138 for implementing MRI imaging (also known as nuclear magnetic resonance, or NMR, imaging) techniques including B1 field shimming. MRI sequence controller 140 can be configured for MR imaging with or without parallel imaging. Moreover, the MRI sequence controller 140 can facilitate one or more preparation scan (pre-scan) sequences, and a scan sequence to obtain a main scan magnetic resonance (MR) image (referred to as a diagnostic image). MR data from pre-scans can be used, for example, to determine shimming parameters for RF coils 115 and/or 121.

The MRI system components 103 include an RF receiver 141 providing input to data processor 142 so as to create processed image data, which is sent to display 124. The MRI data processor 142 is also configured to access previously generated MR data, images, navigator data, system configuration parameters 146, and/or program code structures 144 and 150.

In one embodiment, the MRI data processor 142 includes processing circuitry. The processing circuitry can include devices such as an application-specific integrated circuit (ASIC), configurable logic devices (e.g., simple programmable logic devices (SPLDs), complex programmable logic devices (CPLDs), and field programmable gate arrays (FPGAs), and other circuit components that are arranged to perform the functions recited in the present disclosure.

The processor 142 executes one or more sequences of one or more instructions contained in the program code structures 144 and 150. Alternatively, the instructions can be read from another computer-readable medium, such as a hard disk or a removable media drive. One or more processors in a multi-processing arrangement can also be employed to execute the sequences of instructions contained in the program code structures 144 and 150. In alternative embodiments, hard-wired circuitry can be used in place of or in combination with software instructions. Thus, the disclosed embodiments are not limited to any specific combination of hardware circuitry and software. For example, the program code structure 150 can store instructions that when executed perform the method 200.

Additionally, the term “computer-readable medium” as used herein refers to any non-transitory medium that participates in providing instructions to the processor 142 for execution. A computer readable medium can take many forms, including but not limited to, non-volatile media or volatile media. Non-volatile media includes, for example, optical, magnetic disks, and magneto-optical disks, or a removable media drive. Volatile media includes dynamic memory.

Also illustrated in FIG. 10 is a generalized depiction of an MRI system program storage (memory) 150, where stored program code structures such as instructions to perform the method 200 are stored in non-transitory computer-readable storage media accessible to the various data processing components of the MRI system 100. As those in the art will appreciate, the program store 150 can be segmented and directly connected, at least in part, to different ones of the system 103 processing computers having most immediate need for such stored program code structures in their normal operation (i.e., rather than being commonly stored and connected directly to the MRI system controller 130).

Additionally, the MRI system 100 as depicted in FIG. 10 can be utilized to practice exemplary embodiments described herein. The system components can be divided into different logical collections of “boxes” and typically comprise numerous digital signal processors (DSP), microprocessors and special purpose processing circuits (e.g., for fast A/D conversions, fast Fourier transforming, array processing, etc.). Each of those processors is typically a clocked “state machine” wherein the physical data processing circuits progress from one physical state to another upon the occurrence of each clock cycle (or predetermined number of clock cycles).

Furthermore, not only does the physical state of the processing circuits (e.g., CPUs, registers, buffers, arithmetic units, etc.) progressively change from one clock cycle to another during the course of operation, the physical state of associated data storage media (e.g., bit storage sites in magnetic storage media) is transformed from one state to another during operation of such a system. For example, at the conclusion of an image reconstruction process and/or sometimes an image reconstruction map (e.g., coil sensitivity map, unfolding map, ghosting map, a distortion map etc.) generation process, an array of computer-readable accessible data value storage sites in physical storage media will be transformed from some prior state to a new state wherein the physical states at the physical sites of such an array vary between minimum and maximum values to represent real world physical events and conditions. As those in the art will appreciate, such arrays of stored data values represent and also constitute a physical structure, as does a particular structure of computer control program codes that, when sequentially loaded into instruction registers and executed by one or more CPUs of the MRI system 100, causes a particular sequence of operational states to occur and be transitioned through within the MRI system 100.

Numerous modifications and variations of the present disclosure are possible in light of the above teachings. It is therefore to be understood that within the scope of the appended claims, the invention may be practiced otherwise than as specifically described herein.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for detecting k-space signal inconsistency and suppressing related image artifacts in magnetic resonance imaging, the method comprising:
obtaining magnetic resonance imaging (MRI) data, the MRI data including MR signals as signal data over a period of time, the MRI data being represented as an acquired k-space;
generating, based on the acquired k-space, a correlation matrix;
determining a null space of the correlation matrix;
determining a portion of the acquired k-space included in the null space of the correlation matrix to generate an error k-space, the error k-space representing an artifact present in the MRI data; and
reconstructing an image based on a modified k-space, or by applying a penalty term that is a function of the error k-space,
wherein the modified k-space is generated by performing one of:
removing the generated error k-space from the acquired k-space to generate a clean k-space, as the modified k-space, or
modifying the acquired k-space by
calculating, based on the generated error k-space, weights for k-space samples used in image reconstruction, or
omitting, based on the generated error k-space, k-space samples in image reconstruction.

2. The method of claim 1, further comprising:
determining a location of origin of the artifact;
determining a corresponding coil sensitivity at the determined location of origin of the artifact; and
projecting the error k-space onto a coil sensitivity space at the determined location of origin of the artifact.

3. The method of claim 2, further comprising removing the error k-space projected onto the space of the coil sensitivity at the location of origin of the artifact from the acquired k-space.

4. The method of claim 1, further comprising determining the null space of the correlation matrix using a singular value decomposition (SVD) model or a principal component analysis (PCA) model.

5. The method of claim 4, wherein the step of determining the null space of the correlation matrix further comprises:
determining a singular value threshold, and
determining a singular value hard threshold value based on the SVD model, and retaining eigenvectors that belong to eigenvalues smaller than the determined singular value hard threshold.

6. The method of claim 1, wherein the generated correlation matrix is a Hankel matrix.

7. The method of claim 1, wherein the step of determining the portion of the acquired k-space included in the null space of the correlation matrix further comprises applying a Hankel operation to the acquired k-space.

8. The method of claim 1, further comprising repeating the step of removing the error k-space from the acquired k-space to generate an updated clean k-space.

9. An apparatus for detecting k-space signal inconsistency and suppressing related image artifacts in magnetic resonance imaging, the apparatus comprising:
processing circuitry configured to
obtain magnetic resonance imaging (MRI) data, the MRI data including MR signals as signal data over a period of time, the MRI data being represented as an acquired k-space;
generate, based on the acquired k-space, a correlation matrix;
determine a null space of the correlation matrix;
determine a portion of the acquired k-space included in the null space of the correlation matrix to generate an error k-space, the error k-space representing an artifact present in the MRI data; and
reconstruct an image based on a modified k-space, or by applying a penalty term that is a function of the error k-space,
wherein the modified k-space is generated by performing one of:
removing the generated error k-space from the acquired k-space to generate a clean k-space, as the modified k-space, or
modifying the acquired k-space by
calculating, based on the generated error k-space, weights for k-space samples used in image reconstruction, or
omitting, based on the generated error k-space, k-space samples in image reconstruction.

10. The apparatus of claim 9, wherein the processing circuitry is further configured to:
determine a location of origin of the artifact;
determine a corresponding coil sensitivity at the determined location of origin of the artifact; and
project the error k-space onto a coil sensitivity space at the determined location of origin of the artifact.

11. The apparatus of claim 10, wherein the processing circuitry is further configured to remove the error k-space projected onto the space of the coil sensitivity at the location of origin of the artifact from the acquired k-space.

12. The apparatus of claim 9, wherein the processing circuitry is further configured to determine the null space of the correlation matrix using a singular value decomposition (SVD) model or a principal component analysis (PCA) model.

13. The apparatus of claim 12, wherein in determining the null space of the correlation matrix, the processing circuitry is further configured to:
determine a singular value threshold, and
determine a singular value hard threshold value based on the SVD model, and retaining eigenvectors that belong to eigenvalues smaller than the determined singular value hard threshold.

14. The apparatus of claim 9, wherein the correlation matrix generated by the processing circuitry is a Hankel matrix.

15. The apparatus of claim 9, wherein in determining the portion of the acquired k-space included in the null space of the correlation matrix, the processing circuitry is further configured to applying a Hankel operation to the acquired k-space.

16. The apparatus of claim 9, wherein the processing circuitry is further configured to repeat the removing of the error k-space from the acquired k-space to generate an updated clean k-space.

17. The method of claim 1, wherein the reconstructing step further comprises performing Grappa weights calibration.
